(19) United States
(12) Patent Application Publication
(10) Pub. No.: US 2010/0264439 A1
(43) Pub. Date: Oct. 21, 2010

(54) LED PACKAGE STRUCTURE

(75) Inventors: Chien-Yuan CHEN, Taipei City (TW); Yi-Sheng CHEN, Taipei City (TW)

Correspondence Address: ROSENBERG, KLEIN & LEE, 3458 ELLICOTT CENTER DRIVE-SUITE 101, ELLICOTT CITY, MD, 21043, US

(73) Assignee: POWER DATA COMMUNICATIONS CO., LTD., TAIPEI COUNTY (TW)

(21) Appl. No.: 12/712,536

(22) Filed: Feb. 25, 2010

(30) Foreign Application Priority Data
Apr. 20, 2009 (TW) 098206528

(51) Int. Cl. H01L 33/48

(52) U.S. Cl. 257/98; 257/E33.067

(57) ABSTRACT

A light emitting diode (LED) package structure includes a substrate having a chip disposal area and a recession, a chip installed in the chip disposal area, a silicon connecting element installed at the recession, and a silicon lens disposed at a position corresponding to the recession and coupled to the silicon connecting element, such that the silicon connecting element in the recession can assure the silicon lens to be secured onto the substrate to prevent the silicon lens from falling out.

### BACKGROUND OF THE INVENTION

1. Field of the Invention

The present invention relates to a packaging technology, and more particularly to a light emitting diode package structure.

2. Description of the Related Art

In recent years, the issue of energy supply becomes increasingly serious, and the discharge of carbon dioxide is a main cause of the greenhouse effect, and thus energy saving and carbon reduction become the future trends. In a light emitting diode (LED) which is a P-N junction diode, if a forward voltage is applied to the LED, energy will be discharged in the form of photons to provide a light source. Since LED has a good light emitting efficiency, a power saving feature, and a long life span, the LED plays an important role as a light source in the field of illumination.

However, the LED illumination still has existing issues, and the biggest issue is the high heat generated by the chip installed in the package structure. At present, the light conversion efficiency of a high power LED is approximately equal to 20%, and thus the remaining 80% of the light energy is converted into heat energy. The heat energy not only reduces the life span of the LED chip and reduces the brightness, but also causes problems to the LED such as deteriorating the package adhesive of the LED due to the drawback of the structural design. Heat dissipation is a major concern for overcoming the bottleneck of the LED illumination development.

Besides the heat dissipation issue of a heat source (such as the chip), there are other issues including the ways of resisting a high temperature, assuring a high yield rate, and maintaining a stable long-time use of the package structure. Some solutions of the aforementioned issues were disclosed in R.O.C. Pat. Nos. M299351, M323213 and M344572.

The LED package as disclosed in R.O.C. Pat. No. M299351 comprises: a carrier; a plurality of LED chips, installed onto and electrically connected to the carrier; a circular fixing ring; a plurality of secondary lenses; and a primary lens, wherein the primary lens is installed around a circular fixing portion of the carrier and fixed onto the carrier.

The LED package structure as disclosed in R.O.C. Pat. No. M323213 comprises: a lead frame structure, having an LED chip installed thereon; a casing, having a plurality of fixing portions formed at the periphery of the casing; and a lens, latched to the fixing portions by a pressing method.

The LED package structure as disclosed in R.O.C. Pat. No. M344572 comprises: a package base, having a package portion formed on a first surface of a base, and provided for disposing an LED chip; and a lens structure, having a second surface at an end of the lens structure, and a plurality of sidewall surfaces extended vertically from an end of the second surface. In the foregoing patented invention, an adhesive such as a siloxane resin is coated onto the first surface, the second surface and the sidewall surfaces for binding the first surface, the second surface and the sidewall surfaces surface.

Although the foregoing conventional LED package structure is used in different ways for packaging the LED chip, the same issue of having a loosened lens still exists.

To avoid the aforementioned issue, the conventional LED package structure as shown in FIG. 1 includes a substrate 11, a latch portion 111 and a chip disposal area 113, wherein a lens 15 is latched to the latch portion 111 for packaging a chip 13 onto a surface of the substrate 11.

In this conventional package structure, if the chip 13 continues generating heat from its operation, the lens 15 and the substrate 11 will have different levels of expansions, and the lens may be loosened or even fallen apart, and the LED packaging structure may lose its package protecting effect.

Furthermore, the latch portion 111 of the substrate 11 and the lens 15 are surface mounted and coupled with each other, and thus a gap may be produced easily by the negligence during a soldering process, or by a vibration or a touch, and the surface soldering material may be cracked or peeled off easily by high temperature. In addition, moisture may enter into the gap and result in damages easily, and thus the conventional sealed structure requires further improvements.

Therefore, it is a main subject for related designers and manufacturers to provide an LED package technology that can assure a secured packaging of the LED structure.

### SUMMARY OF THE INVENTION

In view of the shortcomings of the prior art, the inventor of the present invention based on years of experience in the related industry to conduct extensive researches and experiments, and finally developed an LED package structure in accordance with the present invention.

Therefore, it is a primary objective of the present invention to overcome the aforementioned shortcomings and deficiencies of the prior art by providing an LED package structure in accordance with the present invention.

Another objective of the present invention is to provide an LED package structure for maintaining a stable light transmittance.

To achieve the foregoing and other objectives, the present invention provides an LED package structure, comprising: a substrate, having a chip disposal area disposed on the substrate, and a recession disposed around the chip disposal area; a chip, coupled to the chip disposal area; a silicon connecting element, filled into the recession; and a silicon lens, installed at a position corresponding to the recession, and coupled to the silicon connecting element, for packaging the chip.

In the LED package structure, the recession can be a closed recession, such as a circular recession, a rectangular recession or a continuous recession in any other appropriate shape. The recession and the silicon connecting element have a cross-sectional shape selected from the collection of a rectangular shape, a trapeze shape, a V-shape, a semicircular shape, a dove-tail shape and a triangular shape. Of course, the cross-sectional shapes of the recession and the silicon connecting elements can be different. The thickness of the silicon lens is smaller than the cross-sectional width of the recession.

Compared with the prior art, the present invention has the recession disposed around the chip disposal area on a surface of the substrate, and the silicon connecting element and the silicon lens made of the same material are coupled to the recession, and the silicon connecting element and the silicon lens disposed in the recession can be expanded or contracted simultaneously to maintain a secured package structure. In addition, phosphors are distributed uniformly on the silicon lens to provide a stable light transmittance of the package structure.

### BRIEF DESCRIPTION OF THE DRAWINGS

FIG. 1 is a schematic view of a conventional LED package structure;

FIG. 2 is a perspective view of an LED package structure in accordance with a first preferred embodiment of the present invention;

FIG. 3 is a cross-sectional view of an LED package structure in accordance with a first preferred embodiment of the present invention;

FIG. 4 is a cross-sectional view of an LED package structure in accordance with a second preferred embodiment of the present invention; and

FIG. 5 is a cross-sectional view of an LED package structure M accordance with a third preferred embodiment of the present invention.

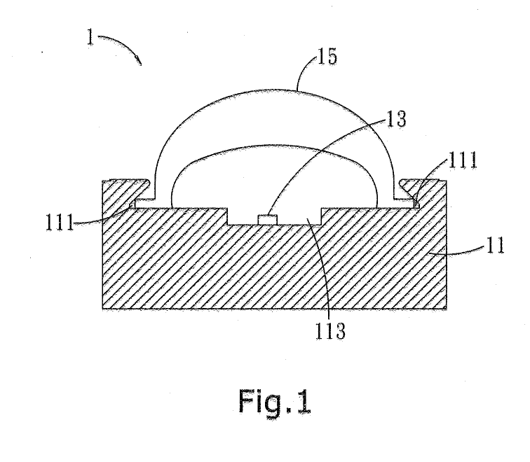

### DETAILED DESCRIPTION OF THE PREFERRED EMBODIMENTS

The technical characteristics of the present invention will become apparent with the detailed description of the preferred embodiments and the illustration of the related drawings.

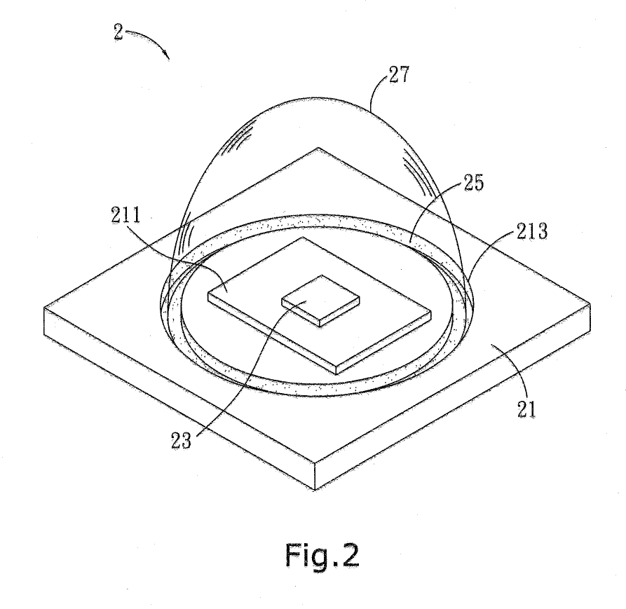

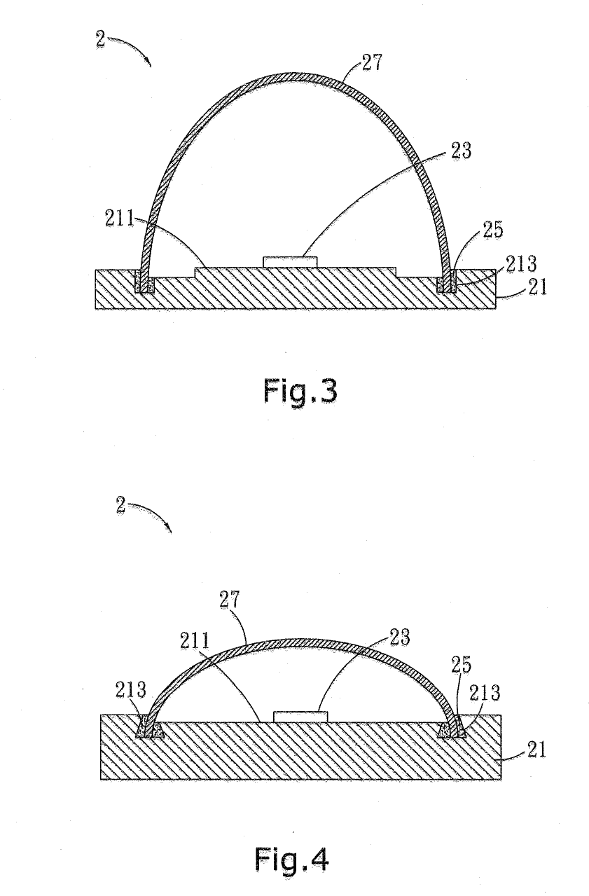

With reference to FIGS. 2 and 3 for a perspective view and a cross-sectional view of an LED package structure in accordance with a first preferred embodiment of the present invention respectively, the LED package structure 1 as shown in FIG. 2 comprises a substrate 21, a chip 23 installed onto the substrate 11, a silicon connecting element 25 disposed at the periphery of the chip 23, and a silicon lens 27 packaged onto the chip 23.

In this preferred embodiment, the substrate 21 is a silicon substrate, and the substrate 21 includes a chip disposal area 211 and a recession 213 disposed around the chip disposal area 211. According to different production requirements, the substrate 21 is not limited to the silicon substrate only, but it can be a low-temperature cofired ceramics (LTCC) substrate, an aluminum substrate, a copper substrate, a printed circuit board, a flexible substrate or any other equivalent substrate. In this preferred embodiment, the recession 213 has a cross-section in a rectangular shape, but the cross-section of the recession 213 can be in a V-shape, a semicircular shape, a dove-tail shape, a triangular shape or any other appropriate shape to meet the requirements of the package structure, the shape of the edge of the silicon lens 27, or the manufacturing process. Of course, the recession 213 can be a closed recession, which is a recession having a continuous shape, or the recessions 213 are formed with an interval apart from each other to assure the packaging effect. The aforementioned arrangement can be modified and practiced easily by those ordinarily skilled in the art, and thus the details will not be described in this specification or illustrated by drawings.

The chip 23 is installed onto the chip disposal area 211. In this preferred embodiment, there is one chip 23, but not limited to such arrangement only. The silicon connecting element 25 is disposed around and inside the recession 213. In this preferred embodiment, the silicon connecting element 25 is a silicone layer filled into the recession 213, such that the silicon connecting element 25 can be formed in the recession 213. After the silicone layer is solidified, the silicon lens 27 is coupled to the silicon connecting element 25, wherein the silicon connecting element 25 of this preferred embodiment is disposed at a position corresponding to the recession 213 and substantially in a rectangular shape, but it is not limited to such arrangement only. The silicon connecting element 25 may have a cross-section in a V-shape, a semicircular shape, a dove-tail shape, a triangular shape or any other shape corresponding to the recession 213, wherein the silicon lens 27 has a thickness smaller than the cross-sectional width of the recession 213, such that the silicon connecting element 25 and the silicon lens 27 can be coupled into the recession 213.

It is noteworthy to point out that the silicon connecting element 25 and the silicon lens 27 are installed in a specific sequence, but the invention is not limited to such arrangement only. In other words, the silicon lens 27 can be inserted into the recession 213 first, and then the silicon connecting element 25 is filled into the gap between the recession 213 and the silicon lens 27, without departing from the spirit of the present invention.

Since the recession 213 is disposed around the external periphery of the chip 23 of the substrate 21, and the silicon connecting element 25 is filled into the recession 213 and coupled to the silicon lens 27, the invention not only provides a strong connection between the silicon lens 27 and the substrate 21, but also provides an excellent waterproof effect through the permeability and water tightness of the silicone. As a result, moisture can be isolated and prevented from entering into the package to assure an excellent packaging effect. In the meantime, a shock-resisting effect can be achieved to prevent the components of the package structure from being loosened easily.

Both silicon connecting element 25 and silicon lens 27 are made of silicon, and thus the coefficient of thermal expansions are the same. When heat is generated by the operation of the chip 23 or the temperature is dropped during a power failure, a tight connection is still maintained at the connecting surface between the silicon connecting element 25 and the silicon lens 27 to overcome the shortcomings of the prior art.

With reference to FIG. 4 for a schematic cross-sectional view of an LED package structure in accordance with a second preferred embodiment of the present invention, the silicon lens 27 of the first preferred embodiment is in a convex semicircular shape, and the difference of the second preferred embodiment from the first preferred embodiment resides on the different shapes of the recession 213 and the silicon lens 27.

In this preferred embodiment, the recession 213 is a recession having a cross-section in a trapeze shape and provided for installing more silicone at the bottom of the recession 213, wherein the silicone acts as the silicon connecting element 25. In other words, the silicon connecting element 25 of this preferred embodiment has a cross-section in a shape different from the cross-sectional shape of the recession 213, and the lens 27 is in an elliptic shape. In other preferred embodiments, the silicon lens 27 may be in a shape other than those disclosed here, and any equivalent shape capable of packaging the chip 23 and providing a good light transmittance can be adopted in the present invention.

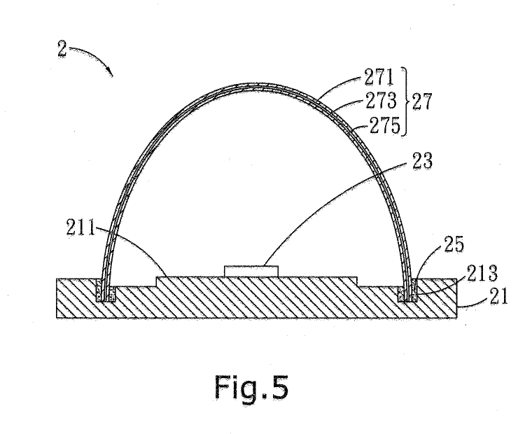

With reference to FIG. 5 for a schematic cross-sectional view of an LED package structure in accordance with a third preferred embodiment of the present invention, the difference of the LED package structure 2 of this preferred embodiment from the first preferred embodiment resides on that the silicon lens 27 is comprised of a first silicon layer 271 and a second silicon layer 273, wherein a phosphor layer 275 is included between the first and second silicon layers 271, 273. In this preferred embodiment, the numerals used for representing respective elements are the same as those used for representing the same respective elements of the first preferred embodiment, and the details of this embodiment will not described here. Since this preferred embodiment assures the phosphor layer 275 to be distributed uniformly between the first silicon layer 271 and the second silicon layer 273, therefore a stable light transmittance can be maintained. In this preferred embodiment, one or more chips 23 can be installed, but the invention is not limited to the quantity as disclosed in the above preferred embodiments only.

It is noteworthy to point out that the electric connection between the substrate 21 and the chip disposal area 211, and the electric connection between the chip disposal area 211 and the chip 23, or the installation of other components, such as the thermal conductive layer or the light reflecting layer (not shown in the figure) installed on a surface of the substrate 21, or thermal conductive component installed between the chip disposal area 211 and the chip 23 as disclosed in the foregoing preferred embodiments are prior arts, and thus the details will not be described in this specification or illustrated by the drawings. In addition, the structure of the chip disposal area 211 is not limited to that described above only, but it can be modified as follows. In the first preferred embodiment, a protruding stem is adopted as the chip disposal area 211 and electrically coupled to an external device (not shown in the figure), but the chip disposal area 211 can also be a concave stem or a coplanar area of the substrate 21, and thus these modifications can be made easily by those ordinarily skilled in the art, thus the details will not be described in this specification or illustrated by drawings.

The present invention improves over the prior art and complies with patent application requirements, and thus is duly filed for the patent application. While the invention has been described by device of specific embodiments, numerous modifications and variations could be made thereto by those generally skilled in the art without departing from the scope and spirit of the invention set forth in the claims.

What is claimed is:

1. A light emitting diode (LED) package structure, comprising:
a substrate, having a chip disposal area disposed on the substrate, and a recession disposed around the chip disposal area;
a chip, coupled to the chip disposal area;
a silicon connecting element, filled into the recession; and
a silicon lens, installed at a position corresponding to the recession, and coupled to the silicon connecting element, for packaging the chip.

2. The LED package structure of claim 1, wherein the recession has a cross-sectional shape selected from the collection of a rectangular shape, a trapeze shape, a V-shape, a semicircular shape, a dove-tail shape and a triangular shape.

3. The LED package structure of claim 1, wherein the silicon lens has a thickness smaller than a cross-sectional width of the recession.

4. The LED package structure of claim 1, wherein the substrate is one selected from the collection of a silicon substrate, a low-temperature cofired ceramics (LTCC) substrate, an aluminum substrate, a copper substrate, a printed circuit board, and a flexible substrate.

5. The LED package structure of claim 1, wherein the silicon connecting element is a silicone layer.

6. The LED package structure of claim 1, wherein the silicon connecting element has a cross-sectional shape corresponding to the cross-sectional shape of the recession.

7. The LED package structure of claim 1, wherein the silicon connecting element has a cross-sectional shape different from the cross-sectional shape of the recession.

8. The LED package structure of claim 1, wherein the silicon lens comprises a first silicon layer, a second silicon layer, and a phosphor layer.
